(19) United States
(12) Patent Application Publication
(10) Pub. No.: US 2021/0012413 A1
(43) Pub. Date: Jan. 14, 2021

(54) WEARABLE ACCESSORY DESIGN RECOMMENDATION THROUGH A TRY ON DEVICE

(71) Applicant: Vasan Sowriraja, Chennai (IN)

(72) Inventor: Vasan Sowriraja, Chennai (IN)

(73) Assignee: Adhyas Software Pvt. Ltd., Chennai (IN)

(21) Appl. No.: 17/023,473

(22) Filed: Sep. 17, 2020

Related U.S. Application Data
(63) Continuation of application No. 17/013,679, filed on Sep. 7, 2020.

(30) Foreign Application Priority Data
Jul. 8, 2019 (IN) 201941027325
Jul. 18, 2019 (IN) 201943028965
Jul. 25, 2019 (IN) 201943030141
Jul. 25, 2019 (IN) 201943030160
Aug. 6, 2019 (IN) 201943031795
Aug. 6, 2019 (IN) 201943031877
Aug. 6, 2019 (IN) 201943031887
Aug. 14, 2019 (IN) 201943032875
Aug. 14, 2019 (IN) 201943032884
Aug. 14, 2019 (IN) 201943032895
Aug. 27, 2019 (IN) 201943034545
Aug. 27, 2019 (IN) 201943034562
Oct. 3, 2019 (IN) 201943040095
Oct. 3, 2019 (IN) 201943040096
Dec. 21, 2019 (IN) 201943053293
Dec. 21, 2019 (IN) 201943053306

(51) Int. Cl. G06Q 30/06; G06T 11/00; G06F 30/10

(52) U.S. Cl. CPC G06Q 30/0643; G06T 11/00; G06T 2200/24; G06F 30/10; G06Q 30/0631

(57) ABSTRACT

A method includes capturing, through a video sensor of a try on device, a video frame of a user of the try on device in real-time and capturing, through another sensor of the try on device, one or more real-time parameter(s) related to an environment of the user and the try on device external thereto and/or a proximity of the user to a display device associated with the try on device. The try on device enables the user to virtually sample a number of designs of a wearable accessory on a body part thereof via a display screen of the display device. The method also includes generating, through the try on device and/or a server communicatively coupled to the try on device, a design of the wearable accessory to be recommended to the user based on the captured one or more real-time parameter(s) and the captured video frame.

### CLAIM OF PRIORITY

This application is a Continuation-in-Part Application of and claims priority to U.S. patent application Ser. No. 17/013,679 titled ENHANCED TRY ON DEVICE TO VIRTUALLY SAMPLE A WEARABLE ACCESSORY THERETHROUGH filed on Sep. 7, 2020, which claims priority to Indian Patent Application No. 201941027325 titled ENHANCED TRY ON DEVICE TO VIRTUALLY SAMPLE A WEARABLE ACCESSORY THERETHROUGH filed on Jul. 8, 2019.

This application also claims priority to the following applications:

(i) Indian Patent Application No. 201943028965 titled WEARABLE ACCESSORY DESIGN RECOMMENDATION THROUGH A TRY ON DEVICE filed on Jul. 18, 2019,

(ii) Indian Patent Application No. 201943030141 titled OPTIMIZING AN ENVIRONMENT OF A USER OF A TRY ON DEVICE EXTERNAL THERETO FOR VIRTUAL SAMPLING OF A WEARABLE ACCESSORY THERETHROUGH filed on Jul. 25, 2019,

(iii) Indian Patent Application No. 201943030160 titled USER BASED OPTIMIZATION OF AN ENVIRONMENT OF A TRY ON DEVICE EXTERNAL THERETO FOR VIRTUAL SAMPLING OF A WEARABLE ACCESSORY THERETHROUGH filed on Jul. 25, 2019,

(iv) Indian Patent Application No. 201943031795 titled ENVIRONMENT OPTIMIZATION FOR VIRTUAL SAMPLING OF A WEARABLE ACCESSORY THROUGH A TRY ON DEVICE filed on Aug. 6, 2019,

(v) Indian Patent Application No. 201943031877 titled SENSOR BASED WEARABLE ACCESSORY DESIGN RECOMMENDATION THROUGH A TRY ON DEVICE filed on Aug. 6, 2019,

(vi) Indian Patent Application No. 201943031887 titled SENSOR BASED ENHANCEMENT OF A TRY ON DEVICE TO VIRTUALLY SAMPLE A WEARABLE ACCESSORY THERETHROUGH filed on Aug. 6, 2019,

(vii) Indian Patent Application No. 201943032875 titled USER BASED DISPLAY OPTIMIZATION ASSOCIATED WITH A TRY ON DEVICE FOR VIRTUAL SAMPLING OF A WEARABLE ACCESSORY THERETHROUGH filed on Aug. 14, 2019,

(viii) Indian Patent Application No. 201943032884 titled SENSOR BASED DISPLAY OPTIMIZATION ASSOCIATED WITH A TRY ON DEVICE FOR VIRTUAL SAMPLING OF A WEARABLE ACCESSORY THERETHROUGH filed on Aug. 14, 2019,

(ix) Indian Patent Application No. 201943032895 titled DISPLAY OPTIMIZATION ASSOCIATED WITH A TRY ON DEVICE FOR VIRTUAL SAMPLING OF A WEARABLE ACCESSORY THERETHROUGH filed on Aug. 14, 2019,

(x) Indian Patent Application No. 201943034545 titled USER PROXIMITY CONTROL IN A TRY ON DEVICE DURING VIRTUAL SAMPLING OF A WEARABLE ACCESSORY THERETHROUGH filed on Aug. 27, 2019,

(xi) Indian Patent Application No. 201943034562 titled EXTERNAL ENVIRONMENT BASED USER PROXIMITY CONTROL IN A TRY ON DEVICE FOR VIRTUAL SAMPLING OF A WEARABLE ACCESSORY THERETHROUGH filed on Aug. 27, 2019,

(xii) Indian Patent Application No. 201943040095 titled DISPLAY BASED OPTIMIZATION OF AN EXTERNAL ENVIRONMENT OF A TRY ON DEVICE FOR VIRTUAL SAMPLING OF A WEARABLE ACCESSORY THERETHROUGH filed on Oct. 3, 2019,

(xiii) Indian Patent Application No. 201943040096 titled DISPLAY BASED ENVIRONMENTAL OPTIMIZATION RELATED TO A TRY ON DEVICE FOR VIRTUAL SAMPLING OF A WEARABLE ACCESSORY THERETHROUGH filed on Oct. 3, 2019,

(xiv) Indian Patent Application No. 201943053293 titled USER VIDEO FRAME BASED OPTIMIZATION IN A TRY ON DEVICE FOR VIRTUAL SAMPLING OF A WEARABLE ACCESSORY THERETHROUGH filed on Dec. 21, 2019, and

(xv) Indian Patent Application No. 201943053306 titled USER VIDEO FRAME BASED WEARABLE ACCESSORY DESIGN RECOMMENDATION THROUGH A TRY ON DEVICE filed on Dec. 21, 2019.

The contents of all the abovementioned applications are incorporated herein in entirety thereof by reference.

### FIELD OF TECHNOLOGY

This disclosure relates generally to try on devices and, more particularly, to a method, a device and/or a system of wearable accessory design recommendation through a try on device.

### BACKGROUND

A try on device may be a device that enables a user thereof to virtually sample a wearable accessory (e.g., eyewear, jewelry, hats, clothes, belts, watches) on a body part of the user via a display screen of a display device associated therewith. The user may select a particular design of the wearable accessory through a user interface of the try on device. The particular design may not fit the body part of the user properly even though said particular design is highly preferred and desired by the user.

### SUMMARY

Disclosed are a method, a device and/or a system of an enhanced try on device of wearable accessory design recommendation through a try on device.

In one aspect, a method includes capturing, through a video sensor of a try on device, a video frame of a user of the try on device in real-time and capturing, through another sensor of the try on device, one or more real-time parameter(s) related to an environment of the user and the try on device external thereto and/or a proximity of the user to a display device associated with the try on device. The try on device enables the user to virtually sample a number of designs of a wearable accessory on a body part thereof via a display screen of the display device. The method also includes generating, through the try on device and/or a server communicatively coupled to the try on device, a design of the wearable accessory to be recommended to the user based on the captured one or more real-time parameter(s) and the captured video frame.

In another aspect, a try on device configured to enable a user to virtually sample a number of designs of a wearable accessory on a body part thereof is disclosed. The try on device includes a memory, a processor communicatively coupled to the memory, and a video sensor communicatively coupled to the processor. The video sensor is configured to capture a video frame of the user in real-time via a display screen of a display device associated with the try on device. The try on device also includes another sensor communicatively coupled to the processor. The another sensor is configured to capture one or more real-time parameter(s) related to an environment of the user and the try on device external thereto and/or a proximity of the user to the display device.

The processor is configured to execute instructions to enable, through the try on device and/or a server communicatively coupled thereto, generation of a design of the wearable accessory to be recommended to the user based on the captured one or more real-time parameter(s) and the captured video frame.

In yet another aspect, a system includes a try on device configured to enable a user to virtually sample a number of designs of a wearable accessory on a body part thereof and a server communicatively coupled to the try on device. The try on device includes a video sensor configured to capture a video frame of the user in real-time via a display screen of a display device associated with the try on device, and another sensor configured to capture one or more real-time parameter(s) related to an environment of the user and the try on device external thereto and/or a proximity of the user to the display device. The server and/or the try on device is configured to generate a design of the wearable accessory to be recommended to the user based on the captured one or more real-time parameter(s) and the captured video frame.

The methods and systems disclosed herein may be implemented in any means for achieving various aspects, and may be executed in a form of a machine-readable medium embodying a set of instructions that, when executed by a machine, causes the machine to perform any of the operations disclosed herein.

Other features will be apparent from the accompanying drawings and from the detailed description that follows.

### BRIEF DESCRIPTION OF THE DRAWINGS

The embodiments of this invention are illustrated by way of example and not limitation in the figures of the accompanying drawings, in which like references indicate similar elements and in which:

FIG. 1 is a schematic view of an eyewear system, according to one or more embodiments.

FIG. 2 is a schematic view of interaction of a customer with an eyewear device of the eyewear system of FIG. 1, according to one or more embodiments.

FIG. 3 is a schematic view of an optimization engine, according to one or more embodiments.

FIG. 4 is a schematic view of functionalities of a light sensor and a proximity sensor of FIG. 2, according to one or more embodiments.

FIG. 5 is a schematic view of communication with a decision engine of FIG. 3, according to one or more embodiments.

FIG. 6 is a schematic view of recommendation of an eyeglass design to the customer of the eyewear system of FIG. 1, according to one or more embodiments.

FIG. 7 is a process flow diagram detailing the operations involved in recommending the eyeglass design of FIG. 6, according to one or more embodiments.

Other features of the present embodiments will be apparent from the accompanying drawings and from the detailed description that follows.

### DETAILED DESCRIPTION

Example embodiments, as described below, may be used to provide a method, a device and/or a system of wearable accessory design recommendation through a try on device. Although the present embodiments have been described with reference to specific example embodiments, it will be evident that various modifications and changes may be made to these embodiments without departing from the broader spirit and scope of the various embodiments.

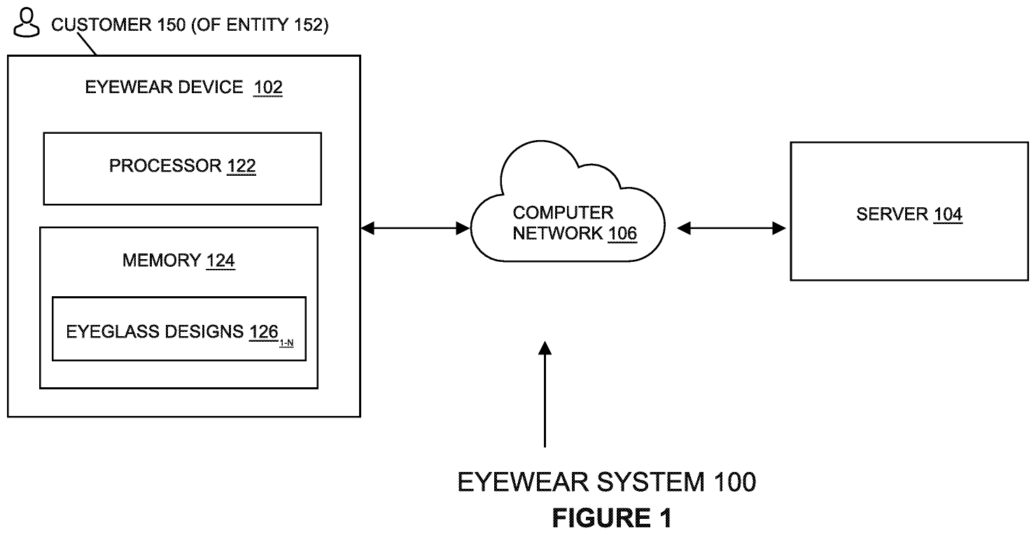

FIG. 1 shows an eyewear system 100, according to one or more embodiments. In one or more embodiments, eyewear system 100 may include an eyewear device 102 communicatively coupled to a server 104 through a computer network 106 (e.g., a wired and/or a wireless network, a Local Area Network (LAN), a Wide Area Network (WAN), Internet, a direct connection). In one or more embodiments, eyewear device 102 may be a smart device including a processor 122 communicatively coupled to a memory 124 (e.g., volatile memory and/or non-volatile memory). In one or more embodiments, memory 124 may include storage locations addressable through processor 122.

In one or more embodiments, eyewear device 102 may enable a customer 150 (example user) of an entity 152 (e.g., a business) associated with eyewear device 102 (e.g., as owner and/or manufacturer of eyewear device 102, as a purchaser of eyewear device 102) to virtually try out and test eyeglass designs 126_{1-N} stored (e.g., pre-stored) in memory 124. For the aforementioned purpose, customer 150 may stand in front of eyewear device 102, and may scroll a list of eyeglass designs 126_{1-N} provided thereto through a user interface provided on eyewear device 102. Customer 150 may also select a particular eyeglass design 126_{1-N} that then is applied onto a real-time video frame thereof on a display for customer 150 to check for suitability, desirability and/or fit.

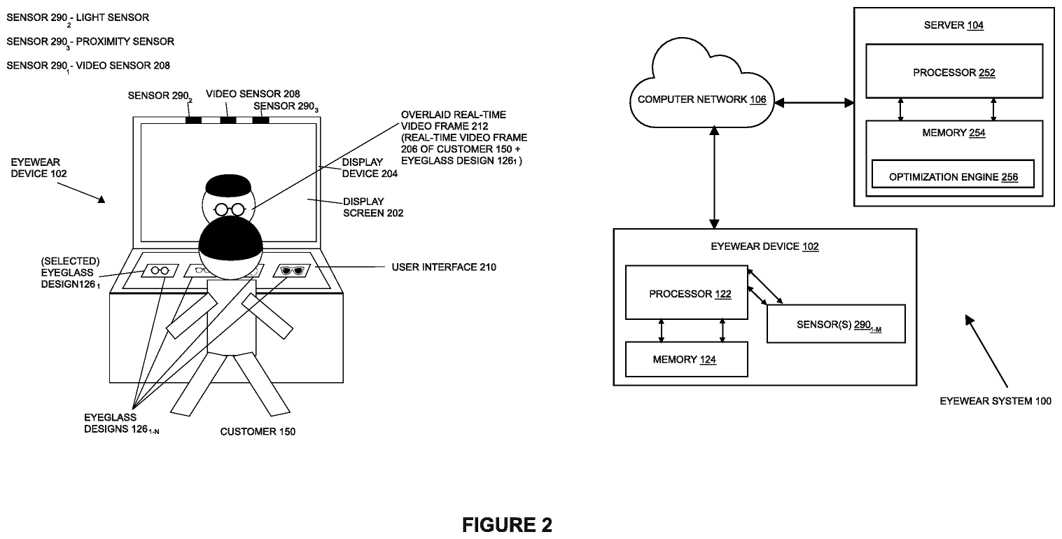

FIG. 2 shows interaction of customer 150 with eyewear device 102, according to one or more embodiments. In an example scenario, customer 150 may walk into a store (e.g., that of entity 152) and may be guided to eyewear device 102 by a staff thereof. Eyewear device 102 may, in one example, include a display screen 202 of a display device 204 onto which a real-time video frame 206 of customer 150 is rendered. To capture real-time video frame 206, eyewear device 102 may include a video sensor 208 (e.g., a video camera). Customer 150 may scroll eyeglass designs 126_{1-N} provided through a user interface 210 of eyewear device 102, as shown in FIG. 2, and select a particular eyeglass design 126_{1-N} (e.g., eyeglass design 126₁, as shown in FIG. 2).

Upon the selection of eyeglass design 126₁ by customer 150, eyewear device 102 may apply eyeglass design 126₁ onto real-time video frame 206 to create overlaid real-time video frame 212. Overlaid real-time video frame 212 may be the real-time video frame/image of customer 150 with the selected eyeglass design 126₁ applied thereto. In one or more embodiments, processor 122 may have capabilities built therein via software engines (e.g., sets of instructions) to detect a face of customer 150 and apply the selected eyeglass design 126₁ at appropriate positions thereof. In one or more embodiments, overlaid real-time video frame 212 may be rendered real-time through display device 204. In certain embodiments, display device 204 may be part of eyewear device 102, as shown in FIG. 2, and, in certain other embodiments, display device 204 may be distinct (e.g., in the case of a television coupled to eyewear device 102; here, display screen 202 may be the screen of the television) from eyewear device 102; in the distinct embodiments, display device 204 may be communicatively coupled (e.g., connected, wired) to eyewear device 102.

FIG. 2 shows server 104 communicatively coupled to eyewear device 102 through computer network 106, according to one or more embodiments. In some embodiments, eyewear device 102 may not be a device with significant computing capabilities. In these embodiments, server 104 may take care of the face detection of customer 150 discussed above. Alternately, in one or more other embodiments, eyewear device 102 may take care of the aforementioned face detection and server 104 may provide other functionalities (to be discussed below).

As shown in FIG. 2, server 104 may include a processor 252 (e.g., one or more microprocessors, a cluster of processors, a distributed network of processors) communicatively coupled to a memory 254 (e.g., a volatile memory and/or a non-volatile memory). In one or more embodiments, memory 254 may include an optimization engine 256 (e.g., a set or sets of instructions) stored therein; said optimization engine 256 may be configured to be executable through processor 252 to realize functionalities thereof. It should be noted that all of the functionalities of optimization engine 256 may additionally or alternately be realized through eyewear device 102 (e.g., through processor 122).

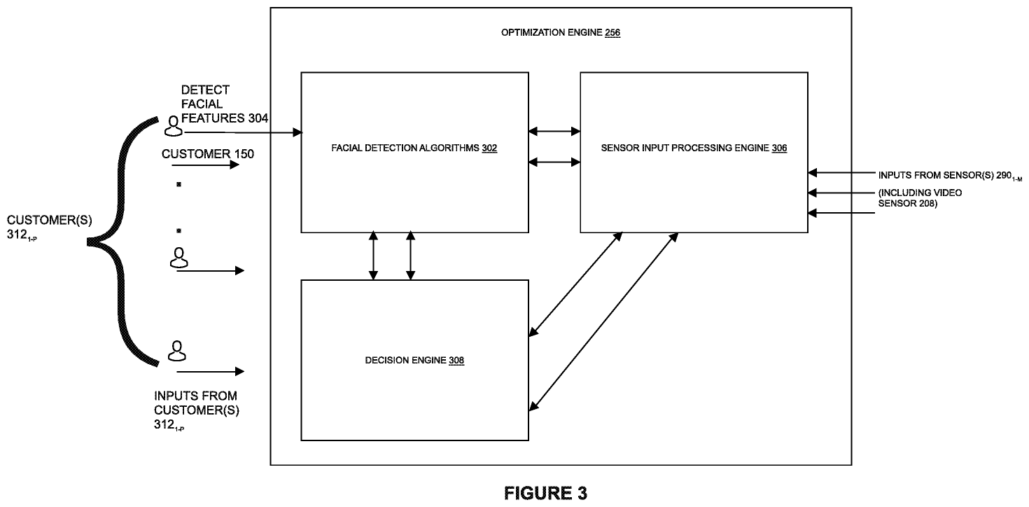

FIG. 3 shows optimization engine 256, according to one or more embodiments. In one or more embodiments, optimization engine 256 may include facial detection algorithms 302 to detect facial features 304 of customer 150 in order to apply eyeglass design 126₁ onto real-time video frame 206. Again, as discussed above, optimization engine 256 and/or facial detection algorithms 302 may be executed by eyewear device 102 in certain embodiments. FIG. 2 shows optimization engine 256 as part of memory 254 of server 104 merely for example purposes. Facial detection algorithms 302 are well known to one skilled in the art. Detailed discussion thereof has, therefore, been skipped for the sake of convenience, brevity and clarity.

In one or more embodiments, optimization engine 256 may also include a sensor input processing engine 306 configured to receive inputs from one or more sensor(s) (e.g., sensor(s) 290_{1-M} including video sensor 208) of optimization engine 256. FIG. 2 shows sensor(s) 290_{1-M} as part of eyewear device 102. Here, sensor(s) 290_{1-M} may be shown as interfaced with processor 122 of eyewear device 102. In one or more embodiments, inputs from video sensor 208 may be received at sensor input processing engine 306; as the selection of eyeglass design 126₁ may result in facial detection algorithms 302 being triggered to enable optimization engine 256 to overlay eyeglass design 126₁ on real-time video frame 206 to effect overlaid real-time video frame 212, said facial detection algorithms 302 may be refined (e.g., parameters thereof modified based on video frame inputs from a number of customers (e.g., including customer 150)) based on inputs from a number of customers; in other words, sensor input processing engine 306 may optimize facial detection algorithms 302 based on customer inputs from video sensor 208.

Additionally, in one or more embodiments, optimization engine 256 may enable scaling of eyeglass designs 126_{1-N} based on customer inputs from video sensor 208. In other words, optimization engine 256 may modify (e.g., increase and/or decrease) dimensions of eyeglass designs 126_{1-N} based on real-time video frames (e.g., real-time video frame 206) of customers (e.g., including customer 150). These functionalities may result in optimization engine 256 offering more exact superimposition of eyeglass design 126₁ onto real-time video frame 206 based on increased inputs from a bunch of customers (e.g., including customer 150). FIG. 3 shows customers 3121-p including customer 150 whose inputs (e.g., inputs from video sensor 208) are taken for optimization through optimization engine 256.

However, the abovementioned functionalities may not take into account additional factor(s) such as a distance of customer 150 from display device 204, an ambience in which customer 150 stands (or, sits) in front of eyewear device 102 to give inputs thereto, an angle at which customer 150 is positioned in front of eyewear device 102/display device 204 with respect to display screen 202 and so on. For the aforementioned purpose, in one or more embodiments, sensors 290_{1-M} may include a light sensor, a proximity sensor and other such types. FIG. 2 shows sensor 290₁ as video sensor 208, sensor 290₂ as the light sensor and sensor 290₃ as the proximity sensor. It should be noted that exemplary embodiments subsume all scenarios involving video sensor 208/sensor 290₁ and at least one other sensor (e.g., sensor 290₂, the light sensor, and/or sensor 290₃, the proximity sensor).

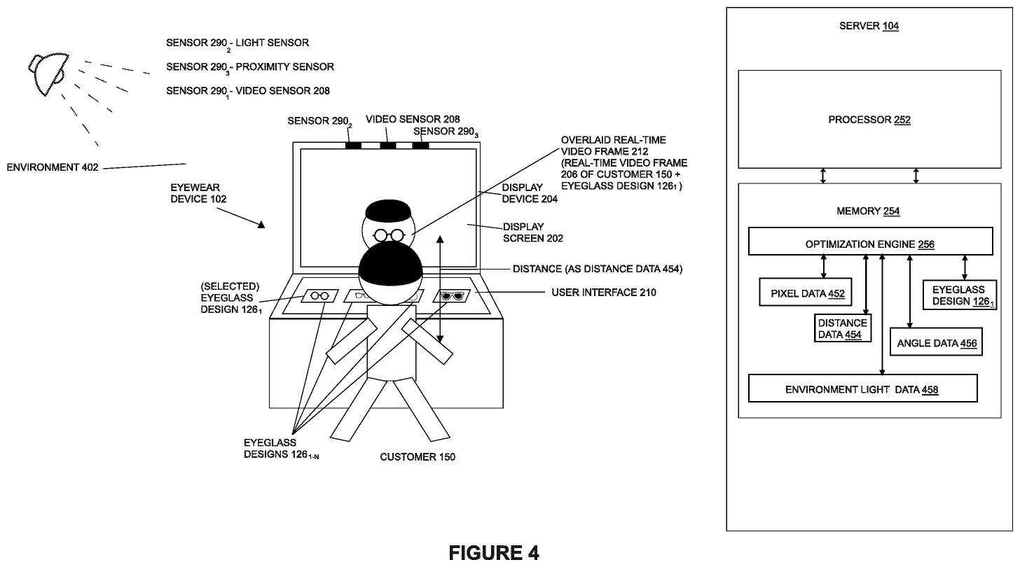

FIG. 4 shows the functionalities of sensor 290₂, the light sensor, and sensor 290₃, the proximity sensor, according to one or more embodiments. Here, sensor 290₂ may be configured to capture a light intensity and/or a light color of an environment 402 of customer 150 real-time. In one or more embodiments, environment 402 may be external to both customer 150 and eyewear device 102. Sensor 290₃ may be configured to capture a distance of customer 150 from display device 204 Sensor 290₃ may also be configured to capture an angle of customer 150 with respect to display screen 202 of display device 204. For example, pixel data of a face of customer 150 may vary more in intensity across the face compared to a reference data of customer 150 (or, another customer) whose face is approximately parallel to display screen 202. These may help sensor input processing engine 306 refine eyeglass design 126₁ and/or pixels of real-time video frame 206 to optimize real-time video frame 206.

FIG. 4 shows pixel data 452 (e.g., stored in memory 254 of server 104; not shown in FIG. 2 but shown in FIG. 4) of customer 150 and eyeglass design 126₁ being refined based on distance data 454 (e.g., distance of customer 150 from display device 204; shown as stored in memory 254 of server 104), angle data 456 (e.g., angle of customer 150 with respect to screen; shown as stored in memory 254 of server 104) and/or environment light data 458 (e.g., a light intensity and/or a light color of environment 402; shown as stored in memory 254 of server 104) obtained through sensor 290₂ and sensor 290₃. It is obvious that exemplary embodiments also cover scenarios where only pixel data 452 or eyeglass design 126₁ is refined. For example, based on one or more of the additional sensor data (e.g., data from sensor 290₂ and/or sensor 290₃), pixel data 452 may be scaled to fit a pre-stored eyeglass design 126₁. Alternately, pixel data related to eyeglass design 126₁ may be refined based on the one or more of the sensor data discussed above.

It should be noted that the refinement of pixel data 452 may include modifying a size of an image of customer 150 in real-time video frame 206, modifying one or more pixel characteristic(s) (e.g., pixel intensity, color) of pixel data 452, extrapolating pixels to convert an angled image of customer 150 into an image parallel to display screen 202 such that eyeglass design 126₁ may be neatly superimposed onto real-time video frame 206 and so on. Refinement of pixel data related to eyeglass design 126₁ may involve scaling pixels of eyeglass design 126₁, rotating eyeglass design 126₁ to fit an angled image of customer 150, modifying one or more pixel characteristics (e.g., pixel intensity, color) of pixel data relevant to eyeglass design 126₁ and so on. In one or more embodiments, the aforementioned refinement(s) may modify real-time video frame 206, eyeglass design 126₁ and/or overlaid real-time video frame 212. In other words, a modified version of real-time video frame 206 may be superimposed with eyeglass design 126₁, real-time video frame 206 may be overlaid with a modified version of eyeglass design 126₁ or the modified version of real-time video frame 206 may be overlaid with the modified version of eyeglass design 126₁. It should be noted that more complex processing operations are within the scope of the exemplary embodiments discussed herein.

In one or more embodiments, the constant refinement of pixel data 452 and/or eyeglass design 126₁ may also be fed back as input to optimization engine 256 (e.g., facial detection algorithms 302). In one or more embodiments, a modified version of eyeglass design 126₁ may be stored as an eyeglass design 126_{1-N} (e.g., in memory 254 of server 104 and/or memory 124 of eyewear device 102); the corresponding pixel data 452, distance data 454, angle data 456 and/or environment light data 458 may be stored (e.g., in memory 254 of server 104 and/or memory 124 of eyewear device 102) therewith, as discussed above. Referring back to FIG. 3, optimization engine 256 may include a decision engine 308 to which a bunch of personnel are provided access to.

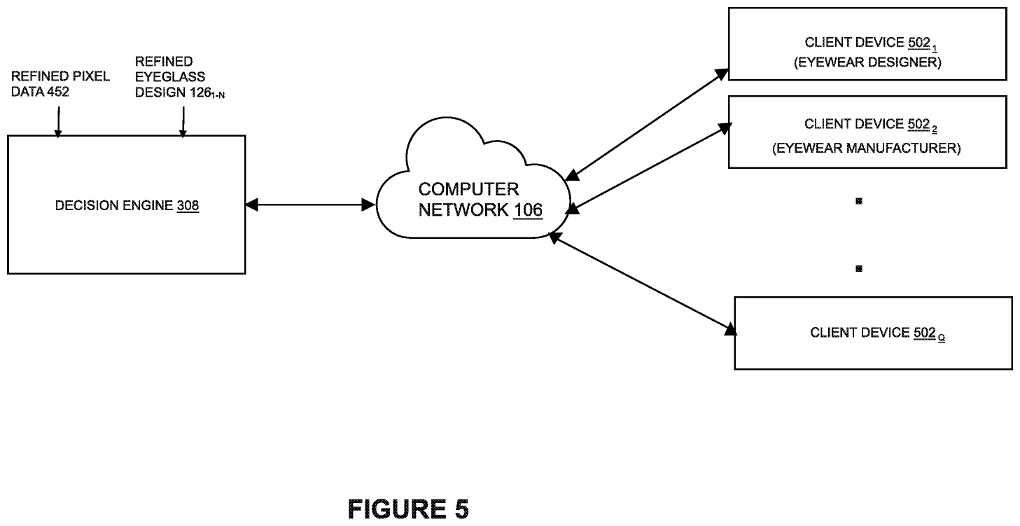

FIG. 5 shows communication with decision engine 308, according to one or more embodiments. In one or more embodiments, the refined pixel data 452 and/or the refined eyeglass design 126_{1-N} may be fed as input to decision engine 308. As seen in FIG. 5, decision engine 308 may be communicatively coupled to a number of client devices 502_{1-Q} (e.g., data processing devices such as laptops, desktops, mobile phones, smart devices) through computer network 106. One client device 502₁ may be associated with an eyewear designer and another client device 5022 may be associated with an eyewear manufacturer, as shown in FIG. 5. In one or more embodiments, decision engine 308 may enable multiple stakeholders take decisions on outputs thereof. For example, the eyewear designer may design new eyewear (e.g., new sizes) based on inputs from decision engine 308. The eyewear manufacturer may manufacture said new eyewear directly based on inputs from decision engine 308 or, alternately, based on communication from the eyewear designer.

In one or more embodiments, decision engine 308 may increase or decrease outputs from one or more of the above stakeholders, thereby impacting the supply chain (e.g., of which client devices 502_{1-Q} may be part of) in an effective manner and increasing efficiency and accuracy therewithin. Moreover, the real-time inputs from customers 3121-p may increase “market readiness” of eyeglass designs 126_{1-N}. Thus, exemplary embodiments discussed herein may provide for increased efficiency of eyewear system 100 and optimization therewithin. It should be noted that exemplary embodiments discussed herein are not merely limited to eyewear. Concepts discussed herein are reasonably extensible to other wearable accessories (e.g., jewelry, clothing, belts, hats, watches) with devices that enable customer 150 to virtually “try on” said wearable accessories; said wearable accessories are wearable on one or more body parts of customer 150. Eyewear device 102 discussed above may be an example of a try-on device that enables customer 150 to try on eyeglass design 126₁ (can also be extended to contact lens designs).

It should be noted that pixel data 452 (or, inputs from video sensor 208/sensor 290₁) and inputs from sensor 290₂ and sensor 290₃ (to generalize, sensors 290_{2-M}; example inputs may be distance data 454, angle data 456 and environment light data 458) may also be leveraged through optimization engine 256 to select an optimum eyeglass design to be presented to customer 150. In other words, the capturing of real-time video frame 206 (or, pixel data 452 therefrom) and the capturing of inputs from the additional sensors 290_{2-M} may enable optimization engine 256/decision engine 308 (e.g., implemented through eyewear device 102 and/or server 104) to select the optimum eyeglass design that best fits customer 150. For example, the optimum eyeglass design (e.g., eyeglass design 126₁) may be selected from eyeglass designs 126_{1-N} based on the abovementioned sensor inputs. As seen above, the sensor inputs may result in scaling of pixel data 452 and/or one or more eyeglass designs 126_{1-N}; the scaling may result in a new eyeglass design being created and/or one or more existing eyeglass designs 126i_N being optimized.

In one or more embodiments, based on the sensor inputs discussed above, customer 150 may be presented with an optimized eyeglass design (e.g., eyeglass design 126₁) from the number of eyeglass designs 126_{1-N}. If the existing eyeglass designs 126_{1-N} do not fit customer 150 well as determined through optimization engine 256, in one or more embodiments, optimization engine 256 may determine an eyeglass design 126_{1-N} (e.g., eyeglass design 126₁) closest in fit to customer 150 based on pixel data 452 and/or the other sensor inputs. In one or more other embodiments, optimization engine 256 may generate a new eyeglass design based on a reference eyeglass design (e.g., eyeglass design 126₁ selected by customer 150; other references utilized are within the scope of the exemplary embodiments discussed herein) and present the new eyeglass design (e.g., through user interface 210) to customer 150. In one or more embodiments, the new eyeglass design may be a modified version of the reference eyeglass design.

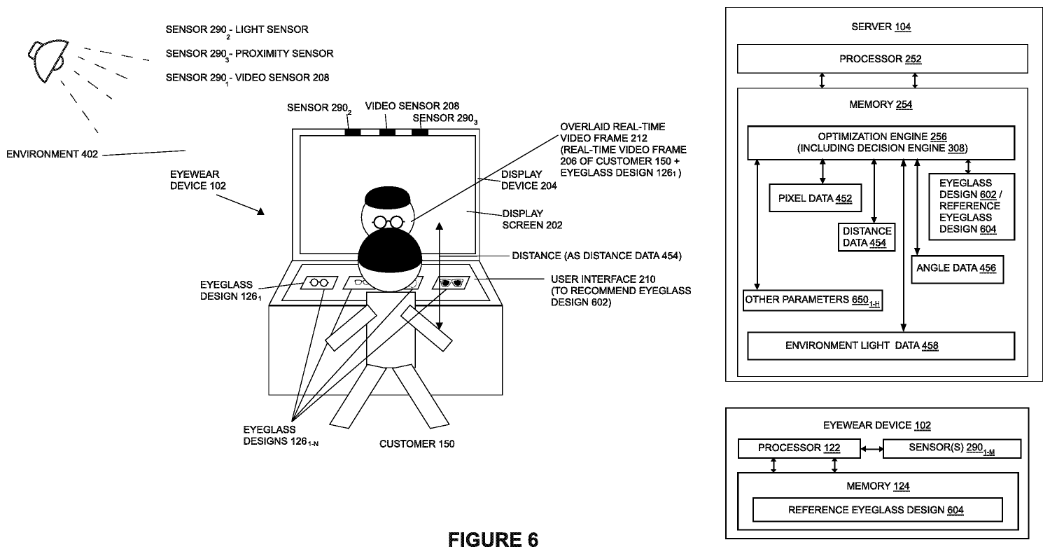

FIG. 6 shows recommendation of an eyeglass design 602 to customer 150, according to one or more embodiments. As seen above, eyeglass design 602 may be a new eyeglass design based on a reference eyeglass design (e.g., eyeglass design 126₁ selected by customer 150) or a specific eyeglass design (e.g., eyeglass design 1263) selected based on a closest fit to customer 150. As seen in FIG. 6, said recommendation of eyeglass design 602 may be made through user interface 210. In one example scenario, customer 150 may select eyeglass design 126₁ through user interface 210 and optimization engine 256/decision engine 308 may recommend eyeglass design 1263 based on closest fit to customer 150. Other parameters (e.g., choice of color, model et al. similar to selected eyeglass design 126₁; other parameters 650_{1-H} related to the aforementioned color, model et al. are shown as stored in memory 254 of server 104; said other parameters 65014i may additionally or alternately be stored in memory 124 of eyewear device 102) may additionally be accounted for by optimization engine 256/decision engine 308 prior to recommendation of eyeglass design 602 to customer 150.

It should be noted that the selection of eyeglass design 126₁ through user interface 210 may be optional on part of customer 150. Eyeglass design 602 may automatically be recommended (e.g., through user interface 210) to customer 150 after the sensor inputs discussed above are obtained. In some other embodiments, the selected eyeglass design 126₁ or another eyeglass design 126_{1-N} may be utilized as a reference eyeglass design 604, as shown stored in memory 124 of eyewear device 102 in FIG. 6 (reference eyeglass design 604 may additionally or alternately be stored in memory 254 of server 104), to select (or, generate) the recommended eyeglass design 602 based on analyses through optimization engine 256. It is possible that the reference eyeglass design 604 may be selected as the recommended eyeglass design 602.

Further, it should be noted that recommended eyeglass design 602 may be overlaid (e.g., automatically/in real-time, on intervention by customer 150 on user interface 210) on real-time video frame 206 to realize overlaid real-time video frame 212 discussed above. In one or more embodiments, the operations involved in recommending eyeglass design 602 to customer 150 (and, optionally, overlaying thereof on real-time video frame 206) may occur in “real-time” relative to perception by customer 150. All reasonable variations are within the scope of the exemplary embodiments discussed herein. It should be noted that all operations discussed above may be performed through eyewear device 102 (e.g., through processor 122) and/or server 104 (e.g., processor 252). All advantages of decision engine 308 and other components discussed above (e.g., with respect to FIGS. 1-5) are applicable across FIG. 6 and related discussion thereof.

Also, instructions associated with optimization engine may be tangibly embodied in a non-transitory medium (e.g., a Compact Disc (CD), a Digital Video Disc (DVD), a Blu-ray Disc®, a hard drive) readable through a data processing device/system (e.g., eyewear device 102, server 104, client devices 502_{1-Q}) configured to execute the aforementioned instructions. All reasonable implementations and variations therein are within the scope of the exemplary embodiments discussed herein.

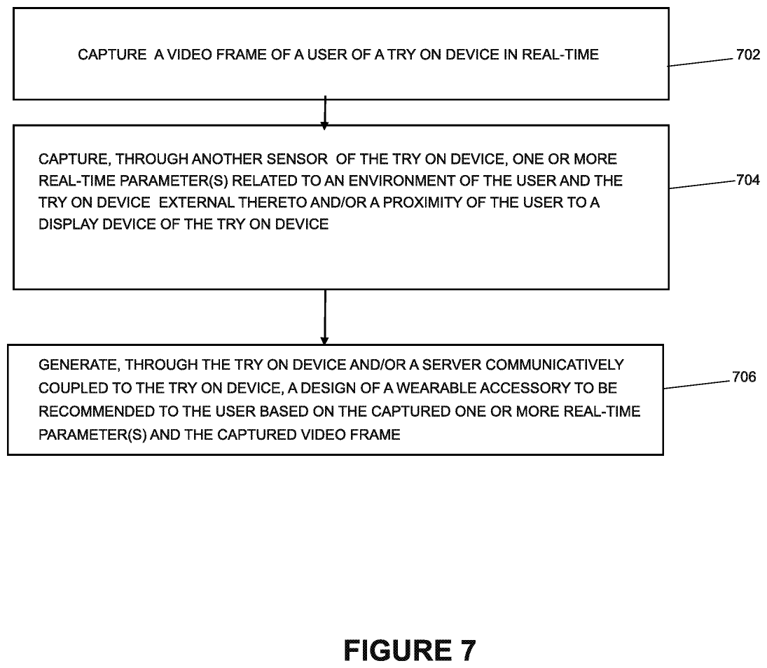

FIG. 7 shows a process flow diagram detailing the operations involved in recommending a design (e.g., eyeglass design 602) of a wearable accessory utilizing a try on device (e.g., eyewear device 102), according to one or more embodiments. In one or more embodiments, operation 702 may involve capturing, through a video sensor (e.g., video sensor 208) of the try on device, a video frame (e.g., real-time video frame 206) of a user (e.g., customer 150) of the try on device in real-time. In one or more embodiments, the try on device may enable the user to virtually sample a number of designs (e.g., eyeglass designs 126_{1-N}) of the wearable accessory on a body part thereof via a display screen (e.g., display screen 202) of a display device (e.g., display device 204) associated with the try on device.

In one or more embodiments, operation 704 may involve capturing, through another sensor (e.g., sensor 290₂, sensor 290₃) of the try on device, one or more real-time parameter(s) related to an environment (e.g., environment light data 458) of the user and the try on device external thereto and/or a proximity (e.g., distance data 454, angle data 456) of the user to the display device. In one or more embodiments, operation 706 may then involve generating, through the try on device and/or a server (e.g., server 104) communicatively coupled to the try on device, the design (e.g., eyeglass design 602) of the wearable accessory to be recommended to the user based on the captured one or more real-time parameter(s) and the captured video frame.

Although the present embodiments have been described with reference to specific example embodiments, it will be evident that various modifications and changes may be made to these embodiments without departing from the broader spirit and scope of the various embodiments. For example, the various devices and modules described herein may be enabled and operated using hardware circuitry (e.g., CMOS based logic circuitry), firmware, software or any combination of hardware, firmware, and software (e.g., embodied in a machine-readable medium). For example, the various electrical structures and methods may be embodied using transistors, logic gates, and electrical circuits (e.g., application specific integrated (ASIC) circuitry and/or Digital Signal Processor (DSP) circuitry).

In addition, it will be appreciated that the various operations, processes, and methods disclosed herein may be embodied in a machine-readable medium and/or a machine accessible medium compatible with a data processing system (e.g., eyewear device 102, server 104, client devices 502_{1-Q}). Accordingly, the specification and drawings are to be regarded in an illustrative rather than a restrictive sense.

What is claimed is:

1. A method comprising:
capturing, through a video sensor of a try on device, a video frame of a user of the try on device in real-time, the try on device enabling the user to virtually sample a plurality of designs of a wearable accessory on a body part thereof via a display screen of a display device associated with the try on device;
capturing, through another sensor of the try on device, at least one real-time parameter related to at least one of: an environment of the user and the try on device external thereto and a proximity of the user to the display device; and
generating, through at least one of: the try on device and a server communicatively coupled to the try on device, a design of the wearable accessory to be recommended to the user based on the captured at least one real-time parameter and the captured video frame.

2. The method of claim 1, comprising at least one of:
enabling the user to virtually sample a plurality of eyewear designs as the plurality of designs through the try on device; and
selecting a particular eyewear design of the plurality of eyewear designs as the recommended design.

3. The method of claim 1, comprising capturing the at least one real-time parameter in accordance with selection of a particular design of the plurality of designs through a user interface of the try on device by the user.

4. The method of claim 1, comprising generating the recommended design of the wearable accessory based on the captured at least one real-time parameter and the captured video frame in accordance with utilizing a reference design of the wearable accessory therefor.

5. The method of claim 1, further comprising overlaying the recommended design on one of: the captured video frame of the user and a modified version of the captured video frame of the user to enable virtual sampling of the recommended design by the user via the display screen.

6. The method of claim 1, comprising providing, as the another sensor, at least one of: a light sensor to capture the at least one real-time parameter related to the environment of the user and the try on device, and a proximity sensor to capture the at least one real-time parameter of the proximity of the user to the display device.

7. The method of claim 1, further comprising at least one of:
feeding the generated design to a decision engine executing on the at least one of: the try on device and the server; and
providing, to a plurality of client devices, access to the decision engine executing on the at least one of: the try on device and the server.

8. A try on device configured to enable a user to virtually sample a plurality of designs of a wearable accessory on a body part thereof, comprising:
a memory;
a processor communicatively coupled to the memory;
a video sensor communicatively coupled to the processor, the video sensor configured to capture a video frame of the user in real-time via a display screen of a display device associated with the try on device; and
another sensor communicatively coupled to the processor, the another sensor configured to capture at least one real-time parameter related to at least one of: an environment of the user and the try on device external thereto and a proximity of the user to the display device,
wherein the processor is configured to execute instructions to enable, through at least one of:
the try on device and a server communicatively coupled thereto:
generation of a design of the wearable accessory to be recommended to the user based on the captured at least one real-time parameter and the captured video frame.

9. The try on device of claim 8, wherein at least one of:
the user is capable of virtually sampling a plurality of eyewear designs as the plurality of designs through the try on device, and
the processor is configured to select a particular eyewear design of the plurality of eyewear designs as the recommended design.

10. The try on device of claim 8, wherein the processor is configured to execute instructions to capture the at least one real-time parameter in accordance with selection of a particular design of the plurality of designs through a user interface of the try on device by the user.

11. The try on device of claim 8, wherein the processor is configured to execute instructions to generate the recommended design of the wearable accessory based on the captured at least one real-time parameter and the captured video frame in accordance with utilizing a reference design of the wearable accessory therefor.

12. The try on device of claim 8, wherein the processor is further configured to execute instructions to overlay the recommended design on one of: the captured video frame of the user and a modified version of the captured video frame of the user to enable virtual sampling of the recommended design by the user via the display screen.

13. The try on device of claim 8, wherein the another sensor is at least one of: a light sensor to capture the at least one real-time parameter related to the environment of the user and the try on device, and a proximity sensor to capture the at least one real-time parameter of the proximity of the user to the display device.

14. The try on device of claim 8, wherein the processor is further configured to execute instructions to at least one of:
feed the generated design to a decision engine executing on the at least one of: the try on device and the server, and
provide, to a plurality of client devices, access to the decision engine executing on the at least one of: the try on device and the server.

15. A system comprising:
a try on device configured to enable a user to virtually sample a plurality of designs of a wearable accessory on a body part thereof, comprising:
a video sensor configured to capture a video frame of the user in real-time via a display screen of a display device associated with the try on device; and
another sensor configured to capture at least one real-time parameter related to at least one of: an environment of the user and the try on device external thereto and a proximity of the user to the display device; and
a server communicatively coupled to the try on device, at least one of: the server and the try on device configured to generate a design of the wearable accessory to be recommended to the user based on the captured at least one real-time parameter and the captured video frame.

16. The system of claim 15, wherein at least one of:
the user is capable of virtually sampling a plurality of eyewear designs as the plurality of designs through the try on device, and
the at least one of: the server and the try on device is configured to select a particular eyewear design of the plurality of eyewear designs as the recommended design.

17. The system of claim 15, wherein the another sensor of the try on device is at least one of: a light sensor configured to capture the at least one real-time parameter related to the environment of the user and the try on device, and a proximity sensor configured to capture the at least one real-time parameter of the proximity of the user to the display device.

18. The system of claim 15, wherein the at least one of: the server and the try on device is configured to generate the recommended design of the wearable accessory based on the captured at least one real-time parameter and the captured video frame in accordance with utilizing a reference design of the wearable accessory therefor.

19. The system of claim 15, wherein the at least one of: the server and the try on device is configured to overlay the recommended design on one of: the captured video frame of the user and a modified version of the captured video frame of the user to enable virtual sampling of the recommended design by the user via the display screen.

20. The system of claim 15, wherein the at least one of: the server and the try on device is further configured to:
feed the generated design to a decision engine executing on the at least one of: the server and the try on device, and
provide, to a plurality of client devices, access to the decision engine executing on the at least one of: the server and the try on device.
